(19) United States
(12) Patent Application Publication
(10) Pub. No.: US 2007/0048990 A1
(43) Pub. Date: Mar. 1, 2007

(54) Method of buffer layer formation for RRAM thin film deposition

(75) Inventors: Wei-Wei Zhuang, Vancouver, WA (US); Sheng Teng Hsu, Camas, WA (US); David R. Evans, Beaverton, OR (US); Tingkai Li, Vancouver, WA (US); Lawrence J. Charneski, Vancouver, WA (US)

Correspondence Address: ROBERT D. VARITZ, 4915 S.E. 33RD PLACE, PORTLAND, OR, 97202, US

(73) Assignee: Sharp Laboratories of America, Inc.

(21) Appl. No.: 11/215,520

(22) Filed: Aug. 30, 2005

(51) Int. Cl. H01L 21/3205

(52) U.S. Cl. 438/593

(57) ABSTRACT

A method of buffer layer formation for RRAM thin film deposition includes preparing a substrate; depositing a bottom electrode on the substrate; depositing a thin layer of a transition metal having a multiple valence on the bottom electrode; depositing a layer of metal oxide on the transition metal; depositing a top electrode on the metal oxide; annealing the substrate and the layers formed thereon; and completing the RRAM.

### FIELD OF THE INVENTION

This invention relates to use of transition metal to form a thin buffer layer on which to deposit the RRAM metal oxide thin films.

### BACKGROUND OF THE INVENTION

Transition metals, e.g., titanium, vanadium, chromium, manganese, iron, and cobalt, are well-known to have multiple valences. These metals oxidize easily when heated, combining with oxygen from air or from an oxide material. Metal oxide thin films, which show reversible resistance change via applying electric pulse, such as Pr_{0.3}Ca_{0.7}MnO₃ (PCMO), were grown on both epitaxial YBa₂Cu₃O₇ (YBCO) and partial epitaxial platinum substrates via pulsed laser ablation (PLA) technique as described by Liu et al., in Electric-pulse-induced reversible resistance change effect in magnetoresistive films, Applied Physics Letters, Vol. 76, number 19, pp. 2749, May 2000; and in U.S. Pat. No. 6,204,139 B1, granted Mar. 20, 2001, for Method for switching the properties of perovskite materials used in thin film resistors.

### SUMMARY OF THE INVENTION

A method of buffer layer formation for RRAM thin film deposition includes preparing a substrate; depositing a bottom electrode on the substrate; depositing a thin layer of a transition metal having a multiple valence on the bottom electrode; depositing a layer of metal oxide on the transition metal; depositing a top electrode on the metal oxide; annealing the substrate and the layers formed thereon; and completing the RRAM.

It is an object of the invention to enhance the switching properties of a metal oxide RRAM.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a block Diagram of the method of the invention.

FIG. 2 depicts switch properties of a PCMO thin film on a cobalt-buffered platinum substrate.

FIG. 3 depicts switch properties having a write parameter of 5 V for 50 ns and a reset parameter of 3 V for 5 μs.

### DETAILED DESCRIPTION OF THE PREFERRED EMBODIMENTS

Considering the oxygen-deficiency properties of RRAM metal oxide thin films, a critically thin, e.g., less than 10 nm, buffer layer of a transition metal, e.g. cobalt, chromium, etc., is introduced between the electrode and RRAM thin film. During a post-annealing process, the transition metal oxidizes, forming a transition metal oxide. Because of the multiple valences of the selected transition metal, the resultant transition metal oxide facilitates formation of a strong oxygen-deficient interface layer with the RRAM metal oxide, which in turn, improves switching properties. RRAM memory cell electrodes, U.S. Pat. No. 6,849,891 B2, of Hsu et al., granted Feb. 1, 2005, and PCMO thin film with memory resistance properties, U.S. patent application Ser. No. 10/831,677, of Zhuang et al., filed Apr. 23, 2004, disclose various RRAM electrodes and metal oxide switching properties, respectively.

Pr_{0.3}Ca_{0.7}MnO₃ (PCMO) thin films have been found to have reversible resistance change properties, as describe by Liu et al., supra. Resistance may be increased to a high resistant state by applying a nanosecond duration electric pulse, e.g., 5 V electrical amplitude and 100 ns pulse duration time. To reset the resistance to a low resistant state, a microsecond duration electric pulse, e.g., having a 3 V amplitude and a 10 μs pulse width, is applied. This resistant switch property renders a PCMO thin film suitable for application in non-volatile memories.

Platinum is a common electrode used in the integration of PCMO thin films. Hsu et al., supra, reported a list of transition metals and metal nitrides which may be used as electrodes in RRAM devices. Recently, in addition to transition metals identified by Hsu et al., a buffer layer formed of a transition metal located between an electrode and a RRAM thin film has been discovered favorably to affect the RRAM electrical properties.

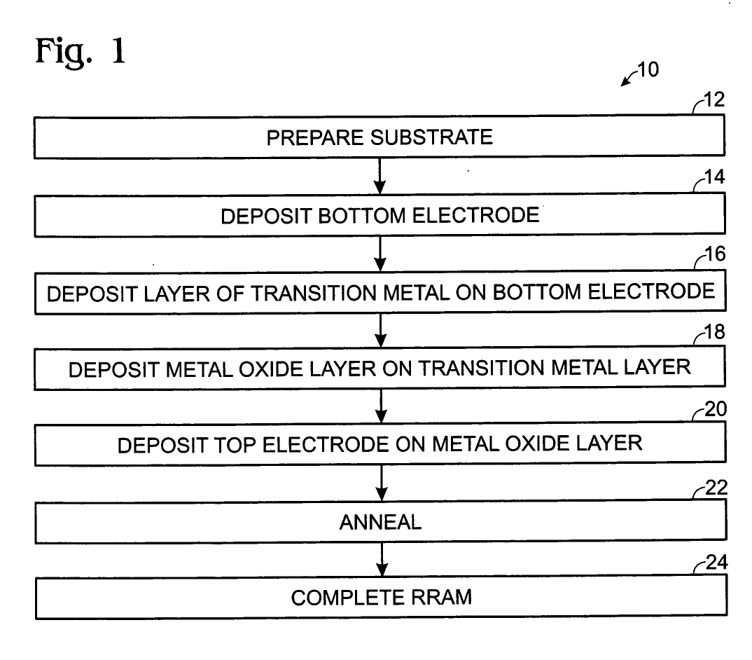

The method of the invention, shown generally at 10 in FIG. 1, begins with preparation of a substrate, step 12, which substrate may be single crystal silicon or silicon dioxide. A bottom electrode is deposited 14, which may be platinum or other noble metal, to a thickness of between about 50 nm to 200 nm. A layer of a transition metal, such as titanium, vanadium, chromium, manganese, iron, cobalt, etc., having a multiple valence, is deposited 16 to a critical thickness of between about 2 nm to 10 nm, using electron beam evaporation. As used herein in connection with the transition metal layer, “thin” means a layer having a thickness of between about 2 nm to 10 nm. A layer of metal oxide, such as PCMO, is deposited 18, to a thickness of between about 80 nm to 800 nm. A top electrode, formed of platinum or some other noble metal, is deposited 20 to a thickness of between about 50 nm to 200 nm on the metal oxide layer. The structure is then annealed 22 in air at a temperature of between about 400° C. to 650° C. for between about two minutes to thirty minutes. The RRAM is completed by encapsulating the substrate, electrodes and metal oxide layers, and metallizing the structure, 24. During a post-annealing process, the transition metal oxidizes, forming a transition metal oxide. Because of the multiple valences of the selected transition metal, the resultant transition metal oxide facilitates formation of a strong oxygen-deficient interface layer with the RRAM metal oxide, which in turn, improves switching properties.

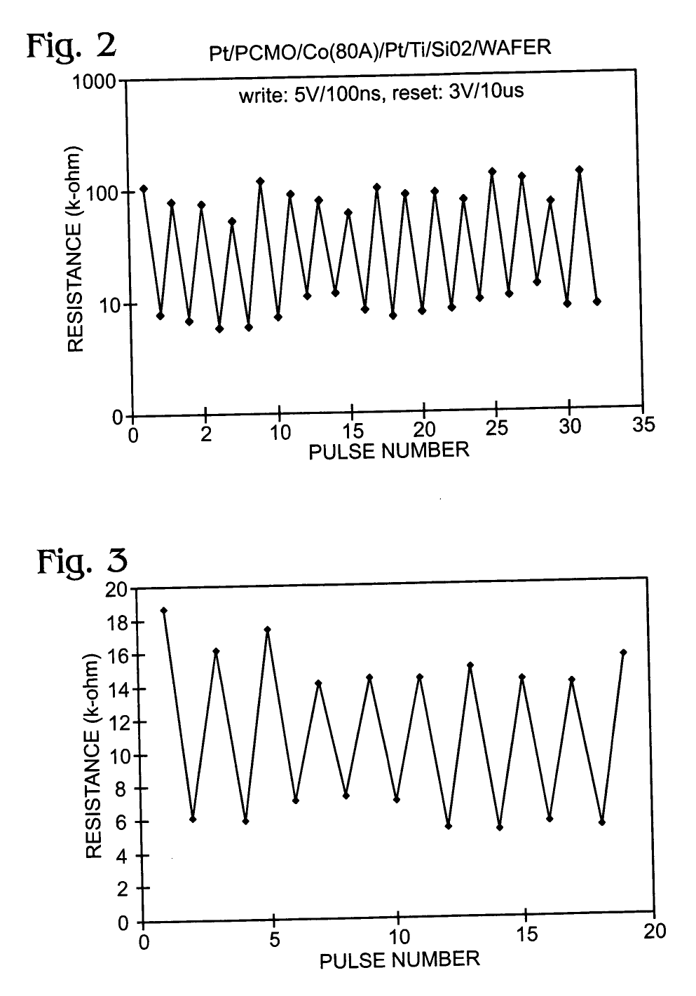

In the first embodiment of fabricating a RRAM according to the method of the invention, cobalt was used as the transition metal buffer layer. A cobalt metal buffer layer was deposited on a platinum metal electrode via electron beam evaporation. The thickness of cobalt buffer layer was about 8 nm. The PCMO RRAM thin film was then spin-coated, to a thickness of about 200 nm. After the deposition of a top platinum electrode, the device was post-annealed in air at about 525° C. for about 20 minutes. Electrical property measurement indicated thin film switch properties, as shown in FIG. 2. The high resistance state, generated by a short 5 V pulse for about 100 ns, was around 100 Kohm, and the low resistance state, reset from high resistance state using a 3 V, 10 μs pulse, was in the level of 10 Kohm.

In examining another buffer layer material, Pr_{0.35}La_{0.35}Ca_{0.3}MnO₃ (PLCMO) was spin-coated on a cobalt-buffered platinum electrode substrate. After post-annealing in air at about 525° C. for about 20 minutes, the electrical property measurement gives the thin film switch properties as shown in FIG. 3. In this case, the high resistance was around 15 Kohm, generated by using a 5 V pulse of about 50 ns, while the low resistance state, around 6 Kohm, reset from high state using 3 V pulse having a duration of about 5 μs.

As shown in the drawings and as described in this Specification, the description includes all steps of the best mode of practicing the invention. There are no additional steps, and the various layers, as described, are formed and/or deposited in sequence without any intervening steps or layers.

In both cases, switch properties were observed. After post-annealing, the cobalt thin buffer layer is oxidized to a cobalt metal oxide. The buffer effect of cobalt metal oxide may come from the cobalt multiple oxidation states, such as Co²⁺ or Co³⁺ formed during the post-annealing process to form a thin oxygen-deficient layer, which may in turn improve the switch properties.

Thus, a method of buffer layer formation for RRAM thin film deposition has been disclosed. It will be appreciated that further variations and modifications thereof may be made within the scope of the invention as defined in the appended claims.

We claim:

1. A method of buffer layer formation for RRAM thin film deposition, comprising:
preparing a substrate;
depositing a bottom electrode on the substrate;
depositing a thin layer of a transition metal having a multiple valence on the bottom electrode;
depositing a layer of metal oxide on the transition metal;
depositing a top electrode on the metal oxide;
annealing the substrate and the layers formed thereon; and
completing the RRAM.

2. The method of claim 1 wherein said depositing a layer of transition metal includes depositing a layer of transition metal taken from the group of transition metals consisting of titanium, vanadium, chromium, manganese, iron, and cobalt, to a thickness of between about 2 nm to 10 nm.

3. The method of claim 1 wherein said depositing a metal oxide includes depositing a layer of metal oxide taken from the group of metal oxides consisting of PCMO and PLCMO to a thickness of between about 80 nm to 300 nm.

4. The method of claim 1 wherein said annealing includes annealing in air at a temperature of between about 400° C. to 650° C. for between about two minutes to thirty minutes.

5. The method of claim 1 wherein said completing the RRAM includes encapsulating the substrate, electrodes and metal oxide layers, and metallizing the structure.

6. A method of buffer layer formation for RRAM thin film deposition, comprising:
preparing a substrate;
depositing a bottom electrode on the substrate;
depositing a thin layer of a transition metal having a multiple valence on the bottom electrode taken from the group of transition metals consisting of titanium, vanadium, chromium, manganese, iron, and cobalt, to a thickness of between about 2 nm to 10 nm;
depositing a layer of metal oxide on the transition metal;
depositing a top electrode on the metal oxide;
annealing the substrate and the layers formed thereon to form an oxygen-deficient layer; and
completing the RRAM.

7. The method of claim 6 wherein said depositing a metal oxide includes depositing a layer of metal oxide taken from the group of metal oxides consisting of PCMO and PLCMO to a thickness of between about 80 nm to 300 nm.

8. The method of claim 6 wherein said annealing includes annealing in air at a temperature of between about 400° C. to 650° C. for between about two minutes to thirty minutes.

9. The method of claim 6 wherein said completing the RRAM includes encapsulating the substrate, electrodes and metal oxide layers, and metallizing the structure.

10. A method of buffer layer formation for RRAM thin film deposition, comprising:
preparing a substrate;
depositing a bottom electrode on the substrate;
depositing a thin layer of a transition metal having a multiple valence on the bottom electrode taken from the group of transition metals consisting of titanium, vanadium, chromium, manganese, iron, and cobalt, to a thickness of between about 2 nm to 10 nm;
depositing a layer of metal oxide on the transition metal;
depositing a top electrode on the metal oxide;
annealing the substrate and the layers formed thereon in air at a temperature of between about 400° C. to 650° C. for between about two minutes to thirty minutes to oxidize the transition metal to a transition metal oxide, forming a thin, oxygen-deficient layer; and
completing the RRAM.

11. The method of claim 10 wherein said depositing a metal oxide includes depositing a layer of metal oxide taken from the group of metal oxides consisting of PCMO and PLCMO to a thickness of between about 80 nm to 300 nm.

12. The method of claim 10 wherein said completing the RRAM includes encapsulating the substrate, electrodes and metal oxide layers, and metallizing the structure.
